(19) United States
(12) Patent Application Publication
(10) Pub. No.: US 2025/0125301 A1
(43) Pub. Date: Apr. 17, 2025

(54) SEMICONDUCTOR DEVICE

(71) Applicant: FUJI ELECTRIC CO., LTD., Kawasaki-shi (JP)

(72) Inventors: Ryo MAETA, Matsumoto-city (JP); Sota WATANABE, Matsumoto-city (JP)

(73) Assignee: FUJI ELECTRIC CO., LTD., Kawasaki-shi (JP)

(21) Appl. No.: 18/784,659

(22) Filed: Jul. 25, 2024

(30) Foreign Application Priority Data
Oct. 12, 2023 (JP) 2023-177038

(51) Int. Cl. H01L 23/00; H01L 25/065

(52) U.S. Cl. CPC H01L 24/48; H01L 24/32; H01L 24/73; H01L 25/0657; H01L 2224/32145; H01L 2224/32225; H01L 2224/48145; H01L 2224/48225; H01L 2224/73265; H01L 2225/0651; H01L 2225/06513; H01L 2924/13091

(57) ABSTRACT

A semiconductor device, including: a semiconductor chip including a switching element, the switching chip having a first control electrode formed on a front surface thereof; and a mirror clamping circuit including a mirror clamping circuit switching element that is located on the first control electrode of the semiconductor chip. The semiconductor chip and the mirror clamping circuit switching element are incorporated in a same package. The switching element is configured to operate in an on state and an off state. The mirror clamping circuit is configured to suppress a rise in a potential of the first control electrode of the switching chip when the switching element is in the off state.

### CROSS-REFERENCE TO RELATED APPLICATION

This application is based upon and claims the benefit of priority of the prior Japanese Patent Application No. 2023-177038, filed on Oct. 12, 2023, the entire contents of which are incorporated herein by reference.

### BACKGROUND OF THE INVENTION

### 1. Field of the Invention

The embodiment discussed herein relates to a semiconductor device.

### 2. Background of the Related Art

In a semiconductor device, a gate diode of a metal-insulator-semiconductor field-effect transistor (MISFET) is located so that in a package an anode is connected onto a source sense terminal and so that in the package a source pad electrode and a gate pad electrode of the MISFET are located on the front surface side (see, for example, Japanese Laid-open Patent Publication No. 2015-126342). Furthermore, a short-circuit metal-oxide-semiconductor field-effect transistor (MOSFET) is connected between a gate and a source of a main-circuit MOSFET, the main-circuit MOSFET and the short-circuit MOSFET are located over different lands, and a source electrode of the main-circuit MOSFET and a source electrode of the short-circuit MOSFET are connected by a wire (see, for example, International Publication Pamphlet No. WO 2012/018073).

In addition, a MOSFET formed on a silicon carbide (SiC) substrate includes a mirror clamping circuit region between a cell region in which a plurality of vertical MOSFET cells are arranged and a gate wiring region (see, for example, Japanese Laid-open Patent Publication No. 2016-174033). Moreover, a mirror clamping source wire is connected from an active mirror clamping transistor to a source sense signal wiring pattern and a mirror clamping gate wire is connected from the active mirror clamping transistor to a gate signal wiring pattern (see, for example, International Publication Pamphlet No. WO 2018/186353).

### SUMMARY OF THE INVENTION

According to an aspect, there is provided a semiconductor device, including: a semiconductor chip including a switching element, the switching chip having a first control electrode formed on a front surface thereof; and a mirror clamping circuit including a mirror clamping circuit switching element that is located on the first control electrode of the semiconductor chip, wherein the semiconductor chip and the mirror clamping circuit switching element are incorporated in a same package, the switching element is configured to operate in an on state and an off state, and the mirror clamping circuit is configured to suppress a rise in a potential of the first control electrode of the switching chip when the switching element is in the off state.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 illustrates an example of the circuit structure of a semiconductor device;

FIG. 3 illustrates an example of the structure of a semiconductor device;

FIG. 4 is an example of a sectional view of the semiconductor device;

FIG. 5 illustrates an example of the structure of a semiconductor device;

FIG. 6 is an example of a sectional view of the semiconductor device;

FIG. 7 illustrates a comparative example and a modification of the arrangement position of a mirror clamping circuit MOSFET;

FIG. 8 illustrates a comparative example and a modification of the arrangement position of a mirror clamping circuit MOSFET;

FIG. 9 illustrates a comparative example and a modification of the arrangement position of a gate electrode of a semiconductor chip; and

FIG. 10 illustrates a comparative example and a modification of the arrangement position of a gate electrode of a semiconductor chip.

### DETAILED DESCRIPTION OF THE INVENTION

An embodiment will now be described with reference to the accompanying drawings. Components in the specification and drawings which have substantially the same functions are marked with the same numeral. By doing so, duplicate description may be omitted. Furthermore, in the following description, an “upper surface” indicates an upward surface from the surface of paper. Similarly, an “upside” or an “upper portion” indicates an upward direction from the surface of paper. A “lower surface” indicates a downward surface from the surface of paper. Similarly, a “lower portion” indicates a downward direction from the surface of paper. These terms mean these directions in all the drawings. The “upper surface,” the “upside,” the “upper portion,” the “lower surface,” and the “lower portion” are simply used as expedient representation for specifying relative positional relationships and do not limit the technical idea of the present disclosure.

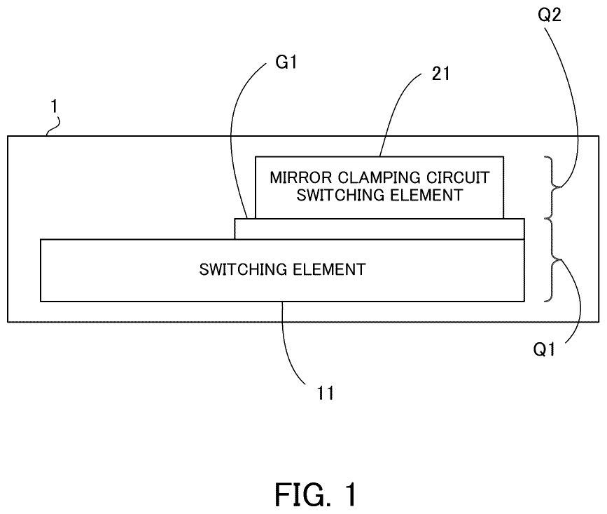

FIG. 1 is a view for describing an example of a semiconductor device. A semiconductor device 1 includes a semiconductor chip Q1 and a mirror clamping circuit Q2. The semiconductor chip Q1 includes a switching element 11 as a main switch. When the switching element 11 is in an off state, the mirror clamping circuit Q2 suppresses a rise in potential of a gate electrode G1 (first control electrode) of the switching chip Q1.

Furthermore, a mirror clamping circuit switching element 21 is located over the gate electrode G1 formed over the front surface of the semiconductor chip Q1 and the semiconductor chip Q1 and the mirror clamping circuit switching element 21 are incorporated in the same package.

With the semiconductor device 1, the mirror clamping circuit switching element 21 is located over the gate electrode G1 formed over the front surface of the switching element 11 and the mirror clamping circuit switching element 21 and the switching element 11 are incorporated in this way in the same package.

This shortens a wiring which connects the switching element 11 of the semiconductor chip Q1 and the mirror clamping circuit switching element 21. Accordingly, a surge voltage generated due to parasitic inductance of the wiring at the time of the switching element 11 being in an off state is suppressed.

A surge voltage generated in a semiconductor device and suppression of the surge voltage will now be described. Semiconductor devices are widely used in power conversion circuits included in devices such as direct current (DC)—DC converters and inverters.

In such devices, semiconductor devices are frequently used for switching operation in which turning on and turning off are repeated at a high speed. In those cases, an overvoltage referred to as a surge voltage may be generated between a control electrode and an output electrode of a switching element due to parasitic inductance of a wiring in a semiconductor device and the semiconductor device may malfunction. Accordingly, measures to suppress a surge voltage are needed.

Furthermore, in recent years, attention has been paid to wide-band-gap semiconductors represented by SiC (such as SiC-MOSFETs and SiC diodes) as high performance semiconductor chips. One of the characteristics of these wide-band-gap semiconductors is that it is possible to increase a switching frequency compared with conventional Si semiconductors.

However, high switching frequency makes it easier for a surge voltage to be generated. Accordingly, in the application of wide-band-gap semiconductors, suppression of a surge voltage is also indispensable.

A mirror clamping circuit is connected between a control electrode and an output electrode of a switching element as a method for suppressing a surge voltage. In such a configuration, the mirror clamping circuit connected between the control electrode and the output electrode of the switching element is driven only when the switching element is in an off state. By doing so, a rise in potential of the control electrode of the switching element is suppressed and a surge voltage is suppressed.

For example, however, if the mirror clamping circuit is apart from the switching element, then parasitic inductance of a wiring which connects the switching element and the mirror clamping circuit increases. As a result, the effect of suppressing a surge voltage achieved by the mirror clamping circuit may be lessened. Accordingly, substrate design which suppresses a rise in potential of the control electrode of the switching element and a surge voltage without increasing parasitic inductance of a wiring is demanded.

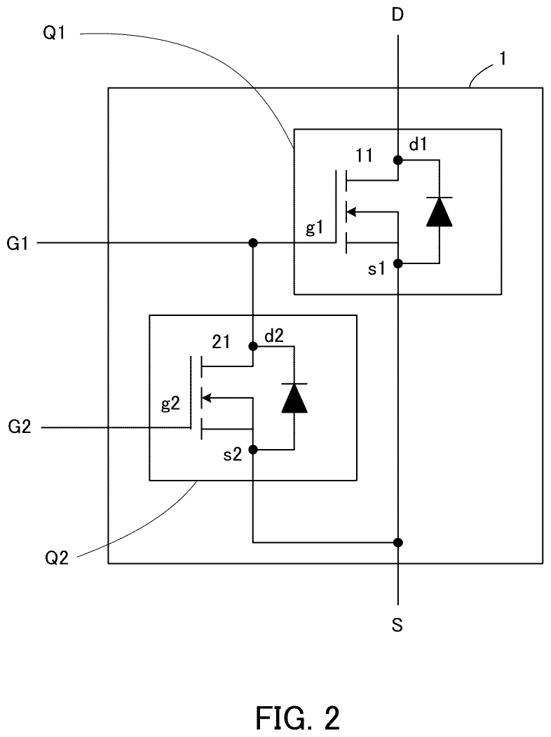

The structure of a semiconductor device according to an embodiment which enhances the effect of suppressing a surge voltage will now be described in detail. FIG. 2 illustrates an example of the circuit structure of a semiconductor device. A semiconductor device 1 includes a semiconductor chip (main circuit) Q1 and a mirror clamping circuit Q2.

For example, a switching element 11 of the semiconductor chip Q1 is formed of a MOSFET and a parasitic diode of the MOSFET. For example, a mirror clamping circuit switching element 21 of the mirror clamping circuit Q2 is formed of a MOSFET and a parasitic diode of the MOSFET. Each of the switching element 11 and the mirror clamping circuit switching element 21 may be formed of other types of elements. For example, each of the switching element 11 and the mirror clamping circuit switching element 21 may be formed of an insulated gate bipolar transistor (IGBT) and a diode connected in inverse parallel therewith.

In the following description, it is assumed that a MOSFET is used for each of the switching element 11 and the mirror clamping circuit switching element 21. The switching element 11 and the mirror clamping circuit switching element 21 may be referred to as a main MOSFET 11 and a mirror clamping circuit MOSFET 21, respectively.

Gate electrodes G1 and G2, a drain electrode D, and a source electrode S are connected to the semiconductor device 1. The gate electrode G1 (first control electrode) is connected to a gate g1 of the main MOSFET 11 and a drain d2 (second input electrode) of the mirror clamping circuit MOSFET 21.

The gate electrode G2 (second control electrode) is connected to a gate g2 of the mirror clamping circuit MOSFET 21. The drain electrode D is connected to a drain d1 (first input electrode) of the main MOSFET 11. The source electrode S is connected to a source s1 of the main MOSFET 11 and a source s2 (second output electrode) of the mirror clamping circuit MOSFET 21.

If an H-level drive signal is applied to the gate electrode G1, then the main MOSFET 11 turns on. At this time, an L-level drive signal is applied to the gate electrode G2. Accordingly, the mirror clamping circuit MOSFET 21 turns off and the mirror clamping circuit Q2 goes into a non-driven state.

Furthermore, if an L-level drive signal is applied to the gate electrode G1, then the main MOSFET 11 turns off. At this time, an H-level drive signal is applied to the gate electrode G2. Accordingly, the mirror clamping circuit MOSFET 21 turns on and the mirror clamping circuit Q2 goes into a driven state.

The mirror clamping circuit MOSFET 21 goes into a driven state and turns on. When the main MOSFET 11 makes the transition from an on state to an off state, the mirror clamping circuit MOSFET 21 extracts electric charges from the gate g1 of the main MOSFET 11. As a result, a fall in voltage at the gate g1 is clamped at a determined voltage.

The mirror clamping circuit Q2 is located between the gate g1 and the source s1 of the main MOSFET 11 and the above control is exercised in this way. By doing so, a surge voltage generated between the gate g1 and the source s1 at the time of the main MOSFET 11 being in an off state is suppressed. In addition, erroneous turning on of the main MOSFET 11 is suppressed.

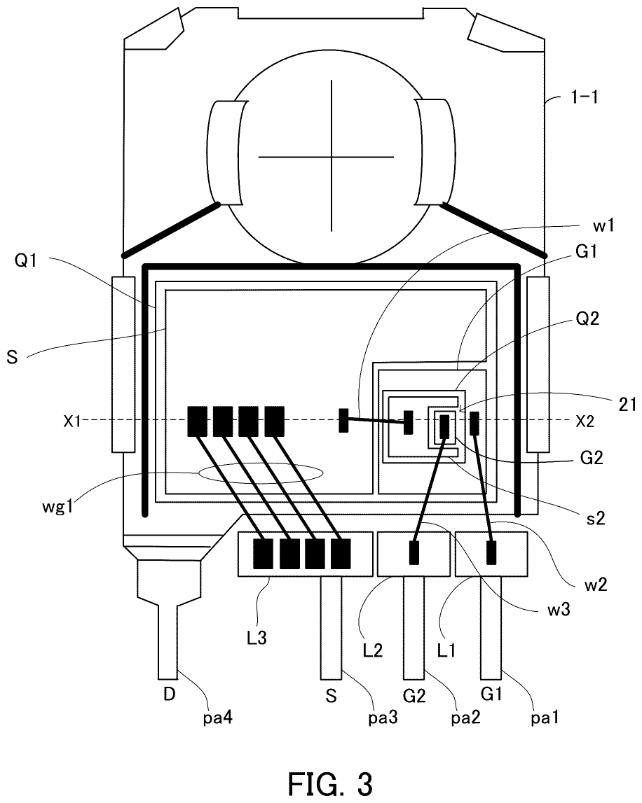

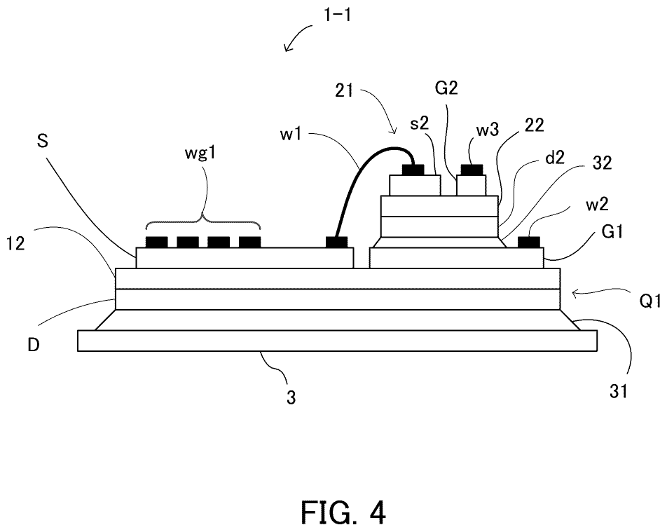

A case where the semiconductor device 1 is applied to a package element (discrete element) will now be described. FIG. 3 illustrates an example of the structure of a semiconductor device. FIG. 4 is an example of a sectional view of the semiconductor device. FIG. 4 is a sectional view taken along the line X1-X2 of FIG. 3. A semiconductor device 1-1 illustrated in FIG. 3 and FIG. 4 is an example of a package element in which four terminals are led out to the outside.

A semiconductor chip Q1 is located over the upper surface of a lead frame 3 illustrated in FIG. 4. A drain electrode D formed on the back surface of a substrate 12 (such as silicon) of the semiconductor chip Q1 is connected via a bonding material 31 (such as solder) to the lead frame 3. A source electrode S is formed over the front surface of the substrate 12 of the semiconductor chip Q1 and a gate electrode G1 is formed apart from the source electrode S.

A mirror clamping circuit MOSFET 21 is located over the gate electrode G1 formed over the front surface of the semiconductor chip Q1. A drain d2 is formed on the back surface of a substrate 22 (such as silicon) of the mirror clamping circuit MOSFET 21 and is connected via a bonding material 32 (conductive bonding material such as solder or plating) to the gate electrode G1. That is to say, the drain d2 (second input electrode) of the mirror clamping circuit MOSFET 21 and the gate electrode G1 (first control electrode) of the semiconductor chip Q1 are connected by the bonding material 32. A source s2 of the mirror clamping circuit MOSFET 21 is formed over the front surface of the substrate 22 of the mirror clamping circuit MOSFET 21 and a gate electrode G2 is formed apart from the source s2.

The source electrode S is connected by a wire w1 to the source s2 of the mirror clamping circuit MOSFET 21. That is to say, the source s2 (second output electrode) of the mirror clamping circuit MOSFET 21 and the source electrode S (first output electrode) of the semiconductor chip Q1 are connected. The gate electrode G1 is connected by a wire w2 to a lead frame post (connection portion) L1 and the gate electrode G2 is connected by a wire w3 to a lead frame post L2. Furthermore, the source electrode S is connected by a wire group wg1 including a plurality of wires to a lead frame post L3. For example, an electrode coated with an Al-Si alloy film (Al-Si electrode) may be formed as each of the above gate electrodes G1 and G2, drain electrode D, and source electrode S.

Terminals pa1, pa2, pa3, and pa4 led out to the outside will now be described. The terminal pa1 (first terminal) is integrally connected to the lead frame post L1 and serves as an external terminal of the gate electrode G1. The terminal pa2 (second terminal) is integrally connected to the lead frame post L2 and serves as an external terminal of the gate electrode G2. That is to say, the gate electrode G1 (first control electrode) is connected by the wire w2 to the terminal pa1 (first terminal) and the gate electrode G2 (second control electrode) is connected by the wire w3 to the terminal pa2 (second terminal).

Furthermore, the terminal pa3 (third terminal) is integrally connected to the lead frame post L3 and serves as an external terminal of the source electrode S. That is to say, the source electrode S (first output electrode) is connected by the wire group wg1 including the plurality of wires to the terminal pa3 (third terminal). The terminal pa4 is connected to the lead frame 3 and serves as an external terminal of the drain electrode D.

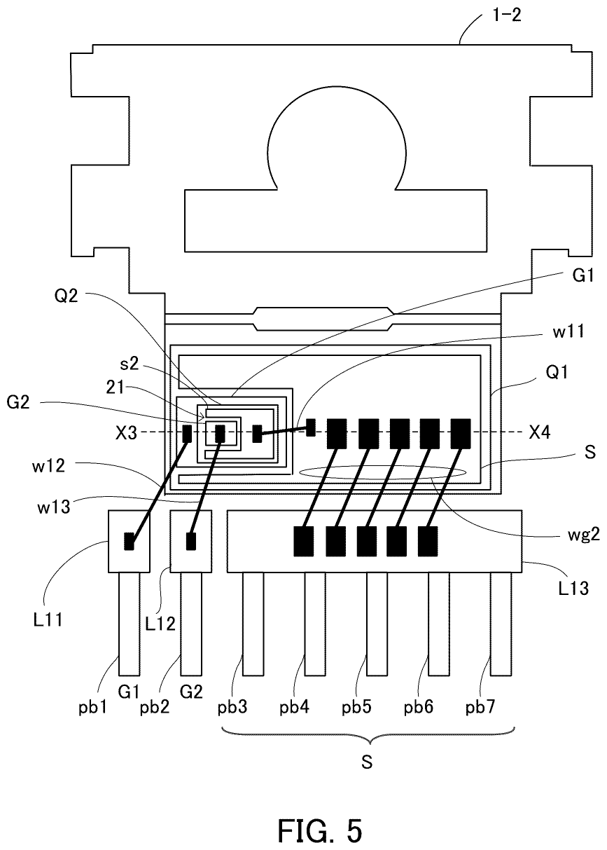

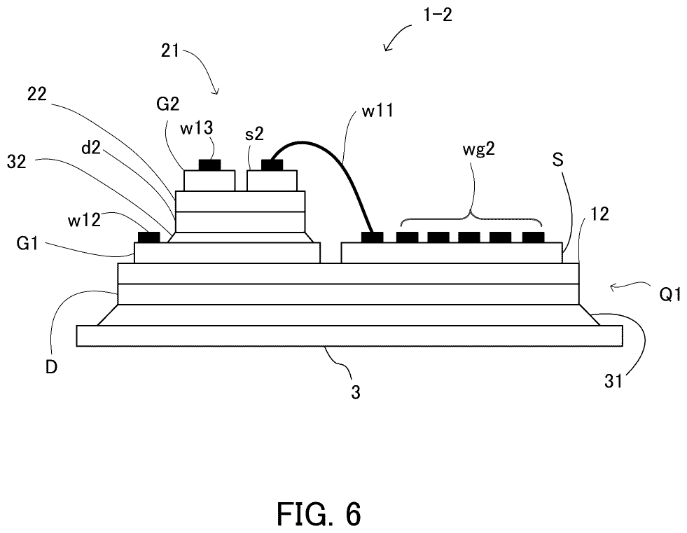

FIG. 5 illustrates an example of the structure of a semiconductor device. FIG. 6 is an example of a sectional view of the semiconductor device. FIG. 6 is a sectional view taken along the line X3-X4 of FIG. 5. A semiconductor device 1-2 illustrated in FIG. 5 and FIG. 6 is an example of a package element in which seven terminals are led out to the outside.

A semiconductor chip Q1 is located over the upper surface of a lead frame 3 illustrated in FIG. 6. A drain electrode D formed on the back surface of a substrate 12 of the semiconductor chip Q1 is connected via a bonding material 31 to the lead frame 3. A source electrode S is formed over the front surface of the substrate 12 of the semiconductor chip Q1 and a gate electrode G1 is formed apart from the source electrode S.

A mirror clamping circuit MOSFET 21 is located over the gate electrode G1 formed over the front surface of the semiconductor chip Q1. A drain d2 is formed on the back surface of a substrate 22 of the mirror clamping circuit MOSFET 21 and is connected via a bonding material 32 to the gate electrode G1. A source s2 of the mirror clamping circuit MOSFET 21 is formed over the front surface of the substrate 22 of the mirror clamping circuit MOSFET 21 and a gate electrode G2 is formed apart from the source s2.

The source electrode S is connected by a wire w11 to the source s2 of the mirror clamping circuit MOSFET 21. The gate electrode G1 is connected by a wire w12 to a lead frame post L11 and the gate electrode G2 is connected by a wire w13 to a lead frame post L12. Furthermore, the source electrode S is connected by a wire group wg2 including a plurality of wires to a lead frame post L13.

Terminals pb1, pb2, pb3, pb4, pb5, pb6, and pa7 led out to the outside will now be described. The terminal pb1 (first terminal) is integrally connected to the lead frame post L11 and serves as an external terminal of the gate electrode G1. The terminal pb2 (second terminal) is integrally connected to the lead frame post L12 and serves as an external terminal of the gate electrode G2. Furthermore, the terminals pb3, pb4, pb5, pb6, and pa7 (third terminals) are integrally connected to the lead frame post L13 and serve as external terminals of the source electrode S. That is to say, the gate electrode G1 is connected by the wire w12 to the terminal pb1 (first terminal), the gate electrode G2 is connected by the wire w13 to the terminal pb2 (second terminal), and the source electrode S is connected by the wire group wg2 including the plurality of wires to the terminals pb3, pb4, pb5, pb6, and pa7 (third terminals).

For example, an aluminum wire having a diameter of 300 to 500 μm is used as each of the above wires w1, w2, w3, w11, w12, and w13 and each of the plurality of wires included in the above wire groups wg1 and wg2. Furthermore, ultrasonic wire bonding or load wire bonding is performed as bonding using wires. Connectors or ribbon wires may be used in place of wires. In this case, one connector may be used in place of the plurality of wires included in the wire group wg1. Similarly, one connector may be used in place of the plurality of wires included in the wire group wg2. For example, a long and narrow metal conductor containing copper as a main ingredient may be used as a connector.

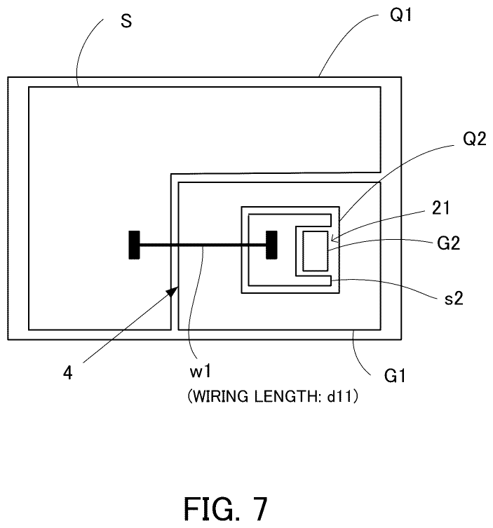

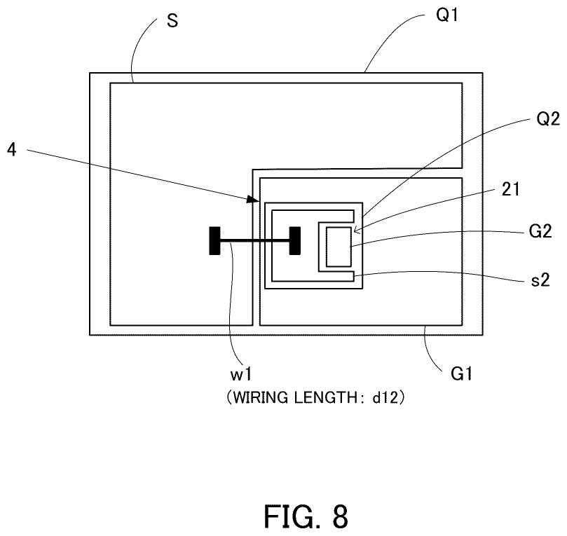

The arrangement position of the mirror clamping circuit MOSFET 21 will now be described. Each of FIG. 7 and FIG. 8 illustrates a comparative example and a modification of the arrangement position of the mirror clamping circuit MOSFET. FIG. 7 illustrates a state in which the mirror clamping circuit MOSFET 21 is arranged near a central portion of the gate electrode G1. FIG. 8 illustrates a state in which the mirror clamping circuit MOSFET 21 is arranged on the side of an outer edge portion 4 of the gate electrode G1.

In FIG. 7, the wiring length of the wire w1 which connects the source s2 of the mirror clamping circuit MOSFET 21 and the source electrode S formed over the front surface of the semiconductor chip Q1 is d11. In FIG. 8, the wiring length of the wire w1 which connects the source s2 and the source electrode S is d12. In this case, d12<d11.

If the mirror clamping circuit MOSFET 21 is arranged in this way on the side of the outer edge portion 4 of the gate electrode G1 (first control electrode), then the wiring length d12 of the wire w1 which connects the source s2 of the mirror clamping circuit MOSFET 21 and the source electrode S is shorter than the wiring length d11 of the wire w1 which connects the source s2 of the mirror clamping circuit MOSFET 21 arranged near the central portion of the gate electrode G1 and the source electrode S. Accordingly, by arranging the mirror clamping circuit MOSFET 21 on the side of the outer edge portion 4 of the gate electrode G1 of the semiconductor chip Q1, parasitic inductance produced by a wiring is reduced. Furthermore, it is preferable to arrange the source s2 of the mirror clamping circuit MOSFET 21 on the side of the outer edge portion 4 of the gate electrode G1. In this case, the wiring length d12 of the wire w1 which connects the source s2 and the source electrode S is still shorter. Accordingly, parasitic inductance produced by a wiring is reduced further.

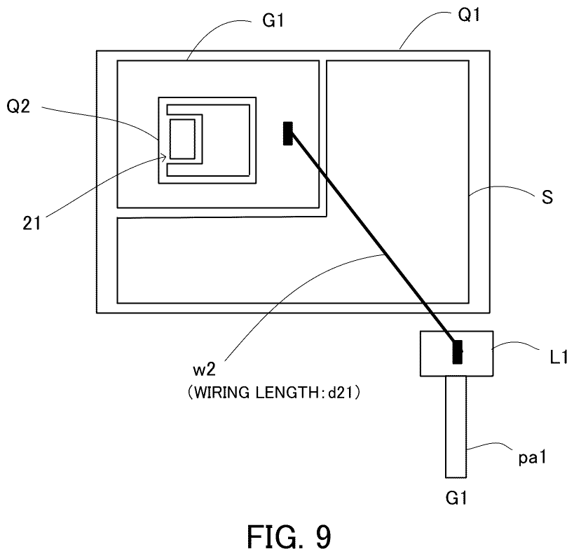

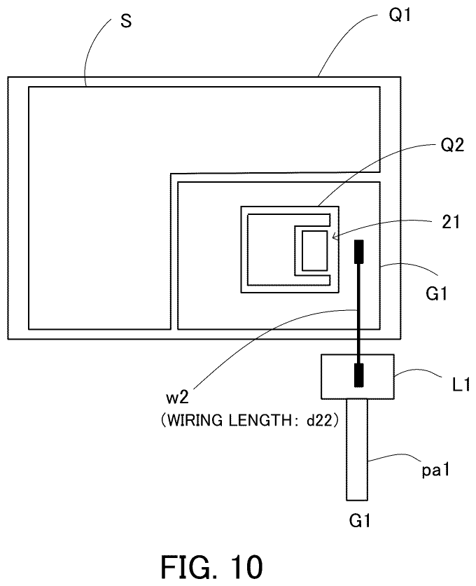

The arrangement position of the gate electrode G1 will now be described. Each of FIG. 9 and FIG. 10 illustrates a comparative example and a modification of the arrangement position of the gate electrode of the semiconductor chip. FIG. 9 illustrates a state in which the gate electrode G1 is formed in a position that is not in the proximity of the terminal pa1 (first terminal). FIG. 10 illustrates a state in which the gate electrode G1 is formed in a position that is in the proximity of the terminal pa1.

In FIG. 9, the wiring length of the wire w2 that connects the gate electrode G1 and the lead frame post L1 to which the terminal pal is connected is d21. In FIG. 10, the wiring length of the wire w2 which connects the gate electrode G1 and the lead frame post L1 is d22. In this case, d22<d21.

If the gate electrode G1 (first control electrode) of the semiconductor chip Q1 is formed in this way in a position which is in the proximity of the terminal pa1 (first terminal), then the wiring length d22 of the wire w2 that connects the gate electrode G1 and the lead frame post L1 to which the terminal pa1 is integrally connected is shorter than the wiring length d21 of the wire w2 extending if the gate electrode G1 is formed in a position that is not in the proximity of the terminal pa1. Accordingly, by forming the gate electrode G1 of the semiconductor chip Q1 in a position that is in the proximity of the first terminal, parasitic inductance produced by a wiring is reduced. Furthermore, the wiring length d22 of the wire w2 is shorter than the wiring length d21 of the wire w2. This prevents the wire w2 from falling.

As has been described in the foregoing, according to the embodiment, the mirror clamping circuit switching element 21 is arranged over the gate electrode G1 formed over the front surface of the semiconductor chip Q1 and the mirror clamping circuit switching element 21 and the semiconductor chip Q1 are incorporated in the same package.

As a result, the switching element 11 and the mirror clamping circuit switching element 21 are arranged at the shortest distance and the wiring length of the wire w1 which connects the source s2 of the mirror clamping circuit switching element 21 and the source electrode S of the switching element 11 of the semiconductor chip Q1 shortens. Accordingly, parasitic inductance of a wiring is reduced and a surge voltage generated due to parasitic inductance of a wiring is suppressed.

Furthermore, because the mirror clamping circuit switching element 21 is arranged over the gate electrode G1 of the semiconductor chip Q1, there is no need to ensure area over the lead frame 3 of the semiconductor device 1 for arranging the mirror clamping circuit switching element 21. This leads to miniaturization of the semiconductor device 1.

The embodiment has been taken as an example. The structure of each section indicated in the embodiment may be replaced by another structure having the same function. Furthermore, any other component or process may be added. Moreover, any two or more of structures (features) of the above embodiment may be combined.

According to an aspect, a surge voltage generated due to parasitic inductance of a wiring is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including a switching element, the switching chip having a first control electrode formed on a front surface thereof; and
a mirror clamping circuit including a mirror clamping circuit switching element that is located on the first control electrode of the semiconductor chip, wherein
the semiconductor chip and the mirror clamping circuit switching element are incorporated in a same package,
the switching element is configured to operate in an on state and an off state, and
the mirror clamping circuit is configured to suppress a rise in a potential of the first control electrode of the switching chip when the switching element is in the off state.

2. The semiconductor device according to claim 1, wherein:
the semiconductor chip further has a first output electrode formed on the front surface thereof; and
the mirror clamping circuit further has:
an input electrode that is connected to the first control electrode of the semiconductor chip via a bonding material, and
a second output electrode that is connected to the first output electrode of the semiconductor chip.

3. The semiconductor device according to claim 2, wherein:
the mirror clamping circuit further has a second control electrode;
the semiconductor device further has a first terminal, a second terminal, and a third terminal;
the first control electrode of the semiconductor chip is connected by a first bonding wire to the first terminal;
the second control electrode of the mirror clamping circuit is connected by a second bonding wire to the second terminal; and
the first output electrode of the semiconductor chip is connected by a plurality of third bonding wires or a plurality of connectors to the third terminal.

4. The semiconductor device according to claim 3, wherein the first control electrode of the semiconductor chip is formed at a proximity of the first terminal.

5. The semiconductor device according to claim 1, wherein
the first control electrode has an outer edge, and
the mirror clamping circuit switching element is located adjacent to the outer edge of the first control electrode.
